(19) United States
(12) Patent Application Publication
(10) Pub. No.: US 2025/0316579 A1
(43) Pub. Date: Oct. 9, 2025

(54) ETCH STOP STRUCTURE FOR IC TO INCREASE STABILITY AND ENDURANCE

(71) Applicant: Taiwan Semiconductor Manufacturing Company, Ltd., Hsinchu (TW)

(72) Inventors: Yung-Chang Chang, Taipei City (TW); Lee-Chuan Tseng, New Taipei City (TW); Chia-Hua Lin, New Taipei City (TW); Shu-Hui Su, Tucheng City (TW)

(21) Appl. No.: 19/243,069

(22) Filed: Jun. 19, 2025

Related U.S. Application Data
(63) Continuation of application No. 18/149,783, filed on Jan. 4, 2023.
(60) Provisional application No. 63/390,082, filed on Jul. 18, 2022.
(60) Provisional application No. 63/408,219, filed on Sep. 20, 2022.

(51) Int. Cl. H01L 23/522; H01L 21/768; H10D 1/68

(52) U.S. Cl. CPC H01L 23/5223; H01L 21/76832; H01L 23/5226; H10D 1/68

(57) ABSTRACT

Various embodiments of the present disclosure are directed towards an integrated circuit (IC) including a plurality of conductive contacts overlying a semiconductor substrate. A plurality of first conductive wires is disposed on the plurality of conductive contacts. A plurality of conductive vias overlies the first conductive wires. An etch stop structure is disposed on the first conductive wires. The plurality of conductive vias extend through the etch stop structure. The etch stop structure includes a first etch stop layer, a first insulator layer, and a second etch stop layer. The first insulator layer is disposed between the first etch stop layer and the second etch stop layer.

### REFERENCE TO RELATED APPLICATIONS

This Application is a Continuation of U.S. application Ser. No. 18/149,783, filed on Jan. 4, 2023, which claims the benefit of U.S. Provisional Application No. 63/390,082, filed on Jul. 18, 2022 & U.S. Provisional Application No. 63/408,219, filed on Sep. 20, 2022. The contents of the above-referenced patent applications are hereby incorporated by reference in their entirety.

### BACKGROUND

Integrated circuits (ICs) are formed on semiconductor dies comprising millions or billions of transistors. The transistors are configured to act as switches and/or to produce power gains so as to enable logical functionality. ICs also comprise passive devices used to control gains, time constants, and other IC characteristics. One type of passive device is a metal-insulator-metal (MIM) capacitor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated circuit (IC) including an etch stop structure disposed along first conductive wires, where the etch stop structure comprises a first etch stop layer, a first insulator layer, and a second etch stop layer.

FIGS. 2A and 2B illustrate cross-sectional views of some other embodiments of the IC of FIG. 1.

FIGS. 3A and 3B illustrate cross-sectional views of further embodiments of the IC of FIG. 1.

FIGS. 4A-4C illustrate cross-sectional views of various embodiments of an IC including an etch stop structure disposed along first conductive wires, where the etch stop structure comprises a first etch stop layer, a first insulator layer, a second etch stop layer, a second insulator layer, and a third etch stop layer.

FIGS. 5-14 illustrate cross-sectional views of some embodiments of a method for forming an IC comprising an etch stop structure disposed along first conductive wires, where the etch stop structure comprises a first etch stop layer, a first insulator layer, and a second etch stop layer.

FIGS. 15-21 illustrate cross-sectional views of some embodiments of a method for forming an IC comprising an etch stop structure disposed along first conductive wires, where the etch stop structure comprises a first etch stop layer, a first insulator layer, a second etch stop layer, a second insulator layer, and a third etch stop layer.

FIGS. 22-24 illustrate cross-sectional views of some other embodiments of a method for forming an IC comprising an etch stop structure disposed along first conductive wires, where the etch stop structure comprises a first etch stop layer, a first insulator layer, and a second etch stop layer.

FIGS. 25-29 illustrate cross-sectional views of further embodiments of a method for forming an IC comprising an etch stop structure disposed along first conductive wires, where the etch stop structure comprises a first etch stop layer, a first insulator layer, and a second etch stop layer.

FIG. 30 illustrates a flowchart of some embodiments of a method of forming an IC comprising an etch stop structure disposed along first conductive wires, where the etch stop structure comprises a first etch stop layer, a first insulator layer, and a second etch stop layer.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Integrated circuits (ICs) may include a number of semiconductor devices such as a capacitor disposed within and/or over a semiconductor substrate. A capacitor may comprise a dielectric layer disposed between a first conductive layer and a second conductive layer. An interconnect structure overlies the semiconductor substrate and is configured to provide electrical connections to the capacitor. The interconnect structure comprises metallization layers disposed within a dielectric structure. The metallization layers may include a plurality of conductive contacts (e.g., vertical routing), a plurality of conductive wires (e.g., horizonal routing), and a plurality of conductive vias (e.g., vertical routing). The interconnect structure overlies the capacitor and has one or more conductive contacts, vias, and wires electrically coupled to the first conductive layer and the second conductive layer. Bias voltages may be applied to the capacitor by way of the metallization layers.

One challenge with the IC is a connection between the capacitor and lower conductive wires within the interconnect structure. For example, the interconnect structure includes a plurality of conductive contacts coupled to the capacitor and a plurality of first conductive wires disposed on the conductive contacts. Lower conductive vias overlie the first conductive wires such that there is an electrical path between the lower conductive vias and the capacitor (e.g., by way of the first conductive wires and the conductive contacts). During fabrication, an etch stop layer is formed on the plurality of first conductive wires and an upper dielectric layer is formed along the etch stop layer. In some instances, the etch stop layer (e.g., silicon nitride) is deposited at relatively high temperatures (e.g., about 400 degrees Celsius or greater) and/or formed to a relatively high thickness (e.g., greater than about 750 angstroms) that may result in the formation of hillocks along top surfaces of the first conductive wires. Subsequently, a plasma etch may be performed on the upper dielectric layer and/or the etch stop layer to form openings for the lower conductive vias. The hillocks along the first conductive wires may lead to the formation of pin holes in the etch stop layer during the plasma etch, where plasma used in the plasma etch may add charge carriers (e.g., electrons) to the first conductive wires.

Due to power level and/or duration of the plasma etch, a large amount of charge carriers may build up in the first conductive wires and may charge the capacitor. After the plasma etch, a wet etch (e.g., a cleaning process) may be performed, where one or more wet etchants used during the wet etch may interact with the first conductive wires through the pin holes in the etch stop layer. When the first conductive wires are exposed to the one or more wet etchants, galvanic corrosion may occur and/or diffusion of a conductive material (e.g., copper) of the first conductive wires may be accelerated as the capacitor discharges during the wet etch. This may result in defects (e.g., via induce metal island corrosion (VIMIC)) in the subsequently formed conductive vias that reduces an integrity of the electrical path (e.g., due to corrosion and/or voids in the conductive wires and/or vias) between the capacitor and interconnect structure. As a result, a performance of the IC may be negatively affected (e.g., reduced yield, interconnect failure, reduced endurance and/or reliability, etc.).

Various embodiments of the present disclosure are directed towards an IC having an etch stop structure disposed over a plurality of first conductive wires coupled to a capacitor. In some embodiments, the capacitor is disposed within/on a substrate and an interconnect structure overlies the capacitor. The interconnect structure includes a plurality of conductive contacts over the capacitor and a plurality of first conductive wires disposed on the conductive contacts. A plurality of conductive vias overlies the first conductive wires. The etch stop structure is disposed along a top surface of the plurality of first conductive wires and the conductive vias extend through the etch stop structure. The etch stop structure includes a first etch stop layer, a second etch stop layer, and a first insulator layer disposed between the first and second etch stop layers. By virtue of materials, thicknesses, and a layout of the layers in the etch stop structure, the formation of hillocks along the first conductive wires is reduced and the formation of pin holes in the etch stop structure during an etch process (e.g., a plasma etch) is reduced. Further, diffusion of a conductive material (e.g., copper) from the conductive wires during a wet etch process performed after the plasma etch is reduced. As a result, defects (e.g., VIMIC) in the interconnect structure are reduced, thereby increasing the reliability and/or performance of an electrical connection between metallization layers in the interconnect structure and the capacitor. Accordingly, a yield and reliability of the IC is increased.

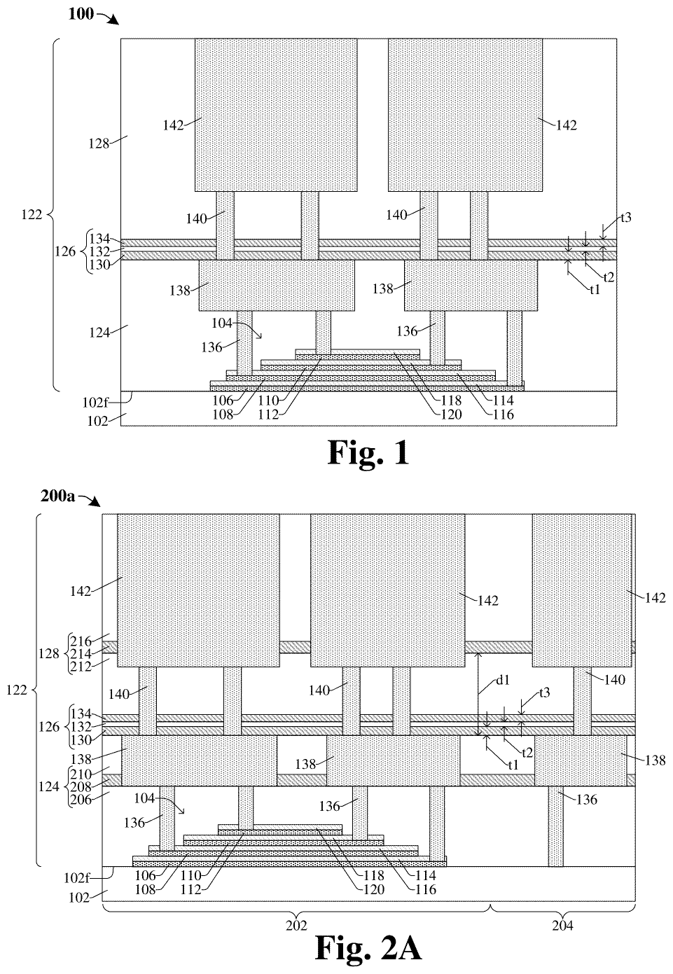

FIG. 1 illustrates a cross-sectional view 100 of some embodiments of an integrated circuit (IC) comprising an etch stop structure disposed along first conductive wires, where the etch stop structure comprises a first etch stop layer, a first insulator layer, and a second etch stop layer.

The IC of FIG. 1 includes an interconnect structure 122 disposed over a semiconductor substrate 102. A capacitor 104 is disposed on a front-side surface 102f of the semiconductor substrate 102. In some embodiments, the capacitor 104 comprises a plurality of conductive layers 106-112 and a plurality of capacitor dielectric layers 114-120 alternatingly disposed between the conductive layers 106-112. In various embodiments, the conductive layers 106-112 may be referred to as capacitor electrode layers. The plurality of conductive layers 106-112 comprises a first conductive layer 106, a second conductive layer 108, a third conductive layer 110, and a fourth conductive layer 112. In some embodiments, the first and third conductive layers 106, 110 may be electrically coupled together by way of the interconnect structure 122 to define a first plate of the capacitor 104, and the second and fourth conductive layers 108, 112 may be electrically coupled together by way of the interconnect structure 122 to define a second plate of the capacitor 104. In some embodiments, the capacitor 104 may be configured as a trench capacitor, a planar capacitor, a cylinder capacitor, a bar capacitor, a dual-damascene capacitor, or the like. In various embodiments, when the capacitor 104 is configured as a trench capacitor the plurality of conductive layers 106-112 and the plurality of capacitor dielectric layers 114-120 are disposed in a trench of the semiconductor substrate 102 that extends below the front-side surface 102f (not shown).

The interconnect structure 122 overlies the semiconductor substrate 102 and is configured to electrically couple devices (e.g., transistors, the capacitor 104, etc.) in a predefined manner. The interconnect structure 122 comprises a plurality of metallization layers disposed in a dielectric structure. The metallization layers include a plurality of conductive contacts 136, a plurality of conductive wires 138, 142, and a plurality of conductive vias 140. The dielectric structure includes a lower dielectric structure 124, an etch stop structure 126, and an upper dielectric structure 128. The plurality of conductive wires 138, 142 comprises a plurality of first conductive wires 138 vertically below a plurality of second conductive wires 142. In some embodiments, the first conductive wires 138 are part of a first layer of conductive wires (e.g., a bottommost layer of conductive wires), where the first conductive wires 138 have a shortest distance to the front-side surface 102f of the semiconductor substrate 102 relative to other conductive wires disposed in the interconnect structure 122 (e.g., relative to the second conductive wires 142). The etch stop structure 126 is disposed along top surfaces of the first conductive wires 138.

In some embodiments, the etch stop structure 126 comprises a first etch stop layer 130, a first insulator layer 132, and a second etch stop layer 134. The first insulator layer 132 is disposed between the first etch stop layer 130 and the second etch stop layer 134. The first etch stop layer 130 has a first thickness t1, the first insulator layer 132 has a second thickness t2, and the second etch stop layer 134 has a third thickness t3. In some embodiments, the first thickness t1 is greater than the third thickness t3 and the second thickness t2 is less than the third thickness t3. In further embodiments, the first and second etch stop layers 130, 134 comprise a first dielectric material (e.g., silicon nitride) and the first insulator layer 132 comprises a second dielectric material (e.g., silicon dioxide) different from the first dielectric material.

During fabrication of the IC, a first etch process is performed on the upper dielectric structure 128 to form a plurality of openings for the conductive vias 140 and a second etch process is performed on the upper dielectric structure 128 and the etch stop structure 126 to expand the openings and expose top surfaces of the first conductive wires 138. The first etch process may comprise at least one a plasma etch performed at a high power to etch through the upper dielectric structure 128. Due to materials, thicknesses, and a layout of layers in the etch stop structure 126, damage (e.g., formation of pin holes) to the etch stop structure 126 is reduced and injection of charge carriers (e.g., electrons) in the first conductive wires 138 is mitigated during the first etch process. Subsequently, a cleaning process (e.g., a wet etch) may be performed on the upper dielectric structure 128 and/or the etch stop structure 126. Since damage to the etch stop structure 126 is mitigated during the first etch process, one or more processing liquids (e.g., wet etchants) utilized during the cleaning process may not reach the first conductive wires 138. As a result, galvanic corrosion and/or diffusion of conductive material (e.g., copper) from the metallization layers of the interconnect structure 122 is/are reduced such that defects (e.g., VIMIC) in the metallization layers (e.g., the first conductive wires 138 and/or the conductive vias 140) of the interconnect structure 122 are mitigated. Accordingly, disposing the etch stop structure 126 along the first conductive wires 138 increase the reliability and/or performance of electrical connections between the capacitor 104 and metallization layers of the interconnect structure 122, thereby increasing an overall performance (e.g., reliability and/or yield) of the IC.

The first etch stop layer 130 may, for example, be or comprise silicon nitride, silicon carbide, silicon carbon-nitride, silicon oxycarbide, silicon oxynitride, a high-k dielectric material, some other dielectric material, or any combination of the foregoing. As used herein, a high-k dielectric material is a dielectric material with a dielectric constant greater than 3.9. The first insulator layer 132 may, for example, be or comprise a low-k dielectric material, phosposilicate glass (PSG), borophosphosilicate glass (BPSG), an oxide such as silicon dioxide, another suitable dielectric material, or any combination of the foregoing. As used herein, a low-k dielectric material is a dielectric material with a dielectric constant less than 3.9. The second etch stop layer 134 may, for example, be or comprise silicon nitride, silicon carbide, silicon carbon-nitride, silicon oxycarbide, silicon oxynitride, a high-k dielectric material, some other dielectric material, or any combination of the foregoing. In some embodiments, the first etch stop layer 130 and the second etch stop layer 134 may both comprise a same dielectric material (e.g., silicon nitride). In further embodiments, the first etch stop layer 130 may comprise a first material (e.g., silicon nitride) and the second etch stop layer 134 may comprise a second material (e.g., silicon carbide) different from the first material.

In some embodiments, the first thickness t1 of the first etch stop layer 130 may be within a range of about 50 to 350 angstroms, within a range of about 350 to 750 angstroms, within a range of about 50 to 750 angstroms, or some other suitable value. In various embodiments, if the first thickness t1 is relatively large (e.g., equal to or greater than 50 angstroms), then the first etch stop layer 130 is sufficiently thick to prevent damage to the first conductive wires 138, for example, from an etch process. In further embodiments, by virtue of the first thickness t1 being less than about 750 angstroms, the first etch stop layer 130 is sufficiently thick to protect the first conductive wires 138 while decreasing a duration the first conductive wires 138 are exposed to high temperatures during deposition of the first etch stop layer 130. This, in part, mitigates the formation of hillocks along top surfaces of the first conductive wires 138. In various embodiments, the second thickness t2 of the first insulator layer 132 may be within a range of about 50 to 175 angstroms, within a range of about 175 to 300 angstroms, within a range of about 50 to 300 angstroms, or some other suitable value. In further embodiments, if the second thickness t2 is relatively large (e.g., equal to or greater than 50 angstroms), then the first insulator layer 132 is sufficiently thick to prevent damage to the first conductive wires 138 and/or to prevent damage (e.g., formation of pin holes) to the first etch stop layer 130. In some embodiments, by virtue of the second thickness t2 being less than about 300 angstroms, a time and/or power level of an etch process utilized to form openings for the conductive vias 140 is reduced thereby reducing fabrication costs and mitigating damage to the first conductive wires 138. In yet further embodiments, the third thickness t3 of the second etch stop layer 134 may be within a range of about 50 to 275 angstroms, within a range of about 275 to 500 angstroms, within a range of about 50 to 500 angstroms, or some other suitable value. In some embodiments, if the thickness t3 is relatively large (e.g., equal to or 50 angstroms), then the second etch stop layer 134 is sufficiently thick to prevent damage to the first conductive wires 138 and/or the first insulator layer 132. In further embodiments, by virtue of the third thickness t3 being less than about 500 angstroms, a time and/or power level of an etch process utilized to form openings for the conductive vias 140 is reduced thereby reducing fabrication costs and mitigating damage to the first conductive wires 138.

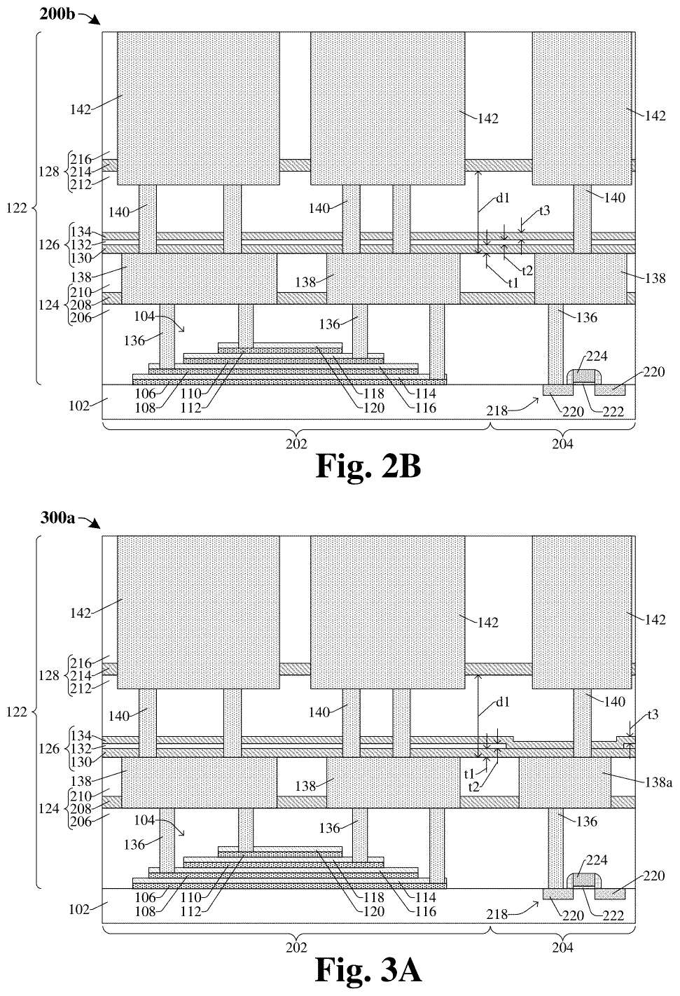

FIG. 2A illustrates a cross-sectional view 200a of some other embodiments of an IC including an etch stop structure disposed along first conductive wires, where the etch stop structure comprises a first etch stop layer, a first insulator layer, and a second etch stop layer.

The IC of FIG. 2A comprises a first region 202 neighboring a second region 204. The first region 202 may be configured as a capacitor region where the IC comprises one or more capacitors such as a capacitor 104. The capacitor 104 is disposed within and/or on a semiconductor substrate 102. The semiconductor substrate 102 may, for example, be or comprise silicon, monocrystalline silicon, CMOS bulk, silicon-germanium, a silicon-on-insulator (SOI), some other suitable substrate material, or the like. The second region 204 may be configured as a non-capacitor region, a logic region, or some other suitable device region. In some embodiments the second region 204 is devoid of capacitors. In some embodiments, the capacitor 104 comprises a plurality of conductive layers 106-112 and a plurality of capacitor dielectric layers 114-120 alternatingly disposed between the conductive layers 106-112. In various embodiments, the plurality of conductive layers 106-112 may, for example, be or comprise titanium, tantalum, titanium nitride, tantalum nitride, another conductive material, or any combination of the foregoing. In further embodiments, the plurality of capacitor dielectric layers 114-120 may, for example, be or comprise a high-k dielectric material, aluminum oxide, hafnium oxide, zirconium oxide, titanium oxide, another dielectric material, or any combination of the foregoing.

The interconnect structure 122 overlies the semiconductor substrate 102 and is configured to electrically couple semiconductor devices disposed on and/or over the semiconductor substrate 102 to one another. The interconnect structure comprises a plurality of metallization layers disposed in a dielectric structure. The metallization layers comprise a plurality of conductive contacts 136, a plurality of conductive wires 138, 142, and a plurality of conductive vias 140. The dielectric structure comprises a lower dielectric structure 124, an etch stop structure 126, and an upper dielectric structure 128. The plurality of conductive wires 138, 142 comprises a plurality of first conductive wires 138 underlying a plurality of second conductive wires 142. In some embodiments, the plurality of conductive contacts 136, the plurality of conductive wires 138, 142, and the plurality of conductive vias 140 may, for example, be or comprise aluminum, copper, tungsten, ruthenium, titanium nitride, tantalum nitride, another suitable conductive material, or any combination of the foregoing. In various embodiments, the plurality of conductive contacts 136, the plurality of conductive wires 138, 142, and the plurality of conductive vias 140 may each comprise a conductive body comprising a first conductive material (e.g., copper, aluminum, tungsten, ruthenium, etc.) and a conductive liner comprising a second conductive material (e.g., titanium nitride, tantalum nitride, etc.) different from the first conductive material, where the conductive liner extends along sidewalls and a bottom surface of the conductive body (not shown).

In some embodiments, a subset of the conductive contacts 136 disposed within the first region 202 may contact the plurality of conductive layers 106-112 of the capacitor 104. In further embodiments, a conductive contact 136 disposed within the second region 204 may directly contact the semiconductor substrate 102. In various embodiments, the semiconductor substrate 102 may comprise one or more doped regions, where the conductive contact 136 dispose within the second region 204 is configured to bias the one or more doped regions to a reference voltage (e.g., ground).

The lower dielectric structure 124 may comprise an inter-level dielectric (ILD) layer 206, a first dielectric protection layer 208, and a first inter-metal dielectric (IMD) layer 210. The ILD layer 206 is disposed along the front-side surface 102f of the semiconductor substrate 102 and laterally wraps around the plurality of conductive contacts 136. In some embodiments, the first dielectric protection layer 208 wraps around sidewalls of first conductive wires 138 and has a bottom surface aligned with a bottom surface of the first conductive wires 138. The first IMD layer 210 overlies the first dielectric protection layer 208. The ILD layer 206 and the first IMD layer 210 may, for example, be or comprise an oxide, such as silicon dioxide, a low-k dielectric material, phosposilicate glass (PSG), borophosphosilicate glass (BPSG), an extreme low-k (ELK) dielectric material, another suitable dielectric material, or any combination of the foregoing. The first dielectric protection layer 208 may, for example, be or comprise silicon nitride, silicon carbide, silicon oxynitride, silicon oxycarbide, or the like.

The etch stop structure 126 is disposed along top surfaces of the first conductive wires 138 and a top surface of the first IMD layer 210. In some embodiments, the etch stop structure 126 comprises a first etch stop layer 130, a first insulator layer 132, and a second etch stop layer 134. The first etch stop layer 130 directly contacts the top surfaces of the first conductive wires 138 and the top surface of the first IMD layer 210. The first insulator layer 132 overlies the first etch stop layer 130 and the second etch stop layer 134 overlies the first insulator layer 132. The first etch stop layer 130 has a first thickness t1, the first insulator layer 132 has a second thickness t2, and the second etch stop layer 134 has a third thickness t3. In some embodiments, the first thickness t1 is greater than the third thickness t3 and the second thickness t2 is less than the third thickness t3.

The upper dielectric structure 128 may comprise a second IMD layer 212, a second dielectric protection layer 214, and a third IMD layer 216. The second IMD layer 212 is disposed along a top surface of the etch stop structure 126. The second dielectric protection layer 214 overlies the second IMD layer 212 and the third IMD layer 216 overlies the second dielectric protection layer 214. The conductive vias 140 extend through the second IMD layer 212 and the etch stop structure 126 to contact the plurality of first conductive wires 138. Further, the second conductive wires 142 extend through the third IMD layer 216, the second dielectric protection layer 214, and at least a portion of the second IMD layer 212 to contact the plurality of conductive vias 140.

In various embodiments, during fabrication of the IC of FIG. 2A, an etching process is performed on layers of the upper dielectric structure 128 and layers of the etch stop structure 126 to define openings for the conductive vias 140 and the second conductive wires 142. Due to materials, thicknesses, and a layout of the layers in the etch stop structure 126, damage to the first conductive wires 138 (e.g., due to an injection of charge carriers and/or due to damage from one or more processing liquids) is mitigated. This mitigates defects in the interconnect structure 122 and reduces damage to the capacitor 104, thereby increasing an overall performance and stability of the IC.

The second IMD layer 212 may, for example, be or comprise an oxide, such as silicon dioxide, a low-k dielectric material, phosposilicate glass (PSG), borophosphosilicate glass (BPSG), an ELK dielectric material, another suitable dielectric material, or any combination of the foregoing. The second dielectric protection layer 214 may, for example, be or comprise silicon nitride, silicon carbide, silicon oxynitride, silicon oxycarbide, or the like. Further, the third IMD layer 216 may, for example, be or comprise an oxide, such as silicon dioxide, a low-k dielectric material, an ELK dielectric material, another suitable dielectric material, or any combination of the foregoing. In some embodiments, a thickness of the third IMD layer 216 is greater than thickness of the first and second IMD layers 210, 212.

A distance d1 is defined between a top surface of the lower dielectric structure 124 and a bottom surface of the second dielectric protection layer 214. In some embodiments, the top surface of the lower dielectric structure 124 is aligned with or co-planar with the top surfaces of the first conductive wires 138. In some embodiments, the distance d1 may, for example, be within a range of about 4,000 to 6,500 angstroms, within a range of about 6,500 to 9,000 angstroms, within a range of about 4,000 to 9,000 angstroms, or some other suitable value. In various embodiments, a ratio between the third thickness t3 of the second etch stop layer 134 and the distance d1 (e.g., t3:d1) is within a range of about 1:20 to 1:33 or some other suitable value. In further embodiments, a ratio between the second thickness t2 of the first insulator layer 132 and the distance d1 (e.g., t2:d1) is within a range of about 1:25 to 1:35 or some other suitable value. In yet further embodiments, a sum of the second thickness t2 and the third thickness t3 (e.g., t2+t3) is greater than about 300 angstroms.

FIG. 2B illustrates a cross-sectional view 200b of some alternative embodiments of the IC of FIG. 2A, in which a semiconductor device 218 is disposed within the second region 204. In some embodiments, the first region 202 is configured as a capacitor region and the second region 204 is configured as a logic region. In various embodiments, the semiconductor device 218 is configured as a transistor and may comprise source/drain regions 220, a gate dielectric layer 222, and a gate electrode 224. The source/drain regions 220 may be disposed within the semiconductor substrate 102 on opposing sides of the gate electrode 224. Further, a sidewall spacer is disposed along sidewalls of the gate dielectric layer 222 and sidewalls of the gate electrode 224.

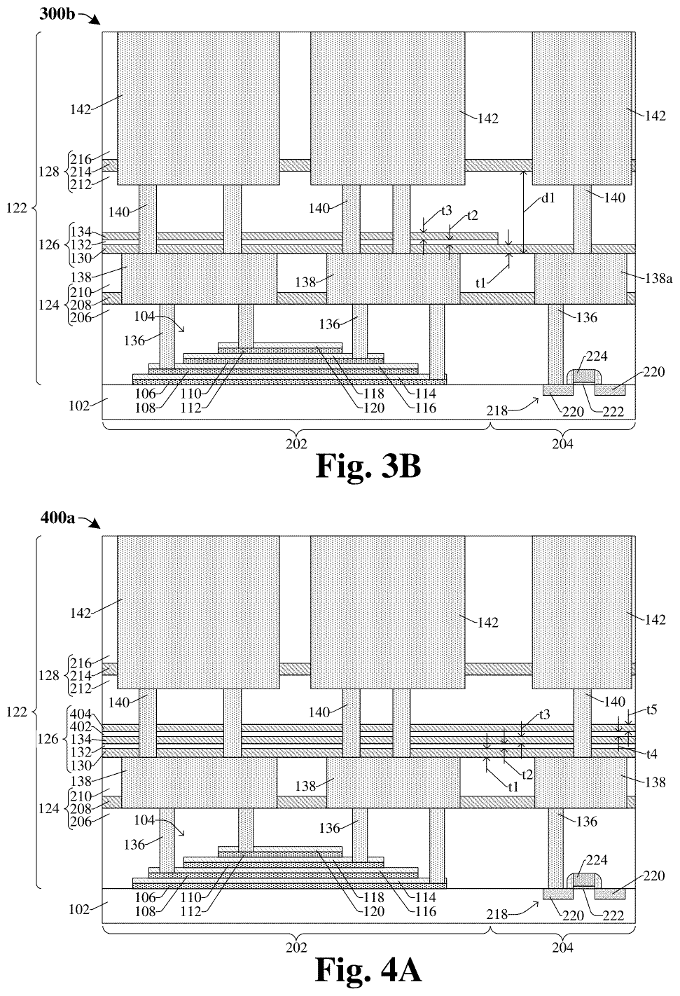

FIG. 3A illustrates a cross-sectional view 300a of some other embodiments of the IC of FIG. 2A, in which the second etch stop layer 134 has a U-shape directly above a first conductive wire 138a within the second region 204. In further embodiments, the first insulator layer 132 is discontinuous within the second region 204 where the second etch stop layer 134 has the U-shape. In such embodiments, the first insulator layer 132 contacts sidewalls of the second etch stop layer 134 that at least partially define the U-shape. In addition, the second IMD layer 212 comprises a protrusion within the second region 204 that extends below a top surface of the etch stop structure 126. In various embodiments, the second etch stop layer 134 directly contacts a top surface of the first etch stop layer 130.

FIG. 3B illustrates a cross-sectional view 300b of some other embodiments of the IC of FIG. 3A, in which the first insulator layer 132 and the second etch stop layer 134 are laterally offset from the second region 204. In some embodiments, the second IMD layer 212 continuously extends from the top surface of the second etch stop layer 134, along a sidewall of the second etch stop layer 134 and a sidewall of the first insulator layer 132, to the top surface of the first etch stop layer 130. In various embodiments, the first insulator layer 132 and the second etch stop layer 134 are discontinuous in a region directly above a first conductive wire 138a within the second region 204. In further embodiments, the second IMD layer 212 comprises a protrusion in the second region 204 that extends below the top surface of the etch stop structure 126.

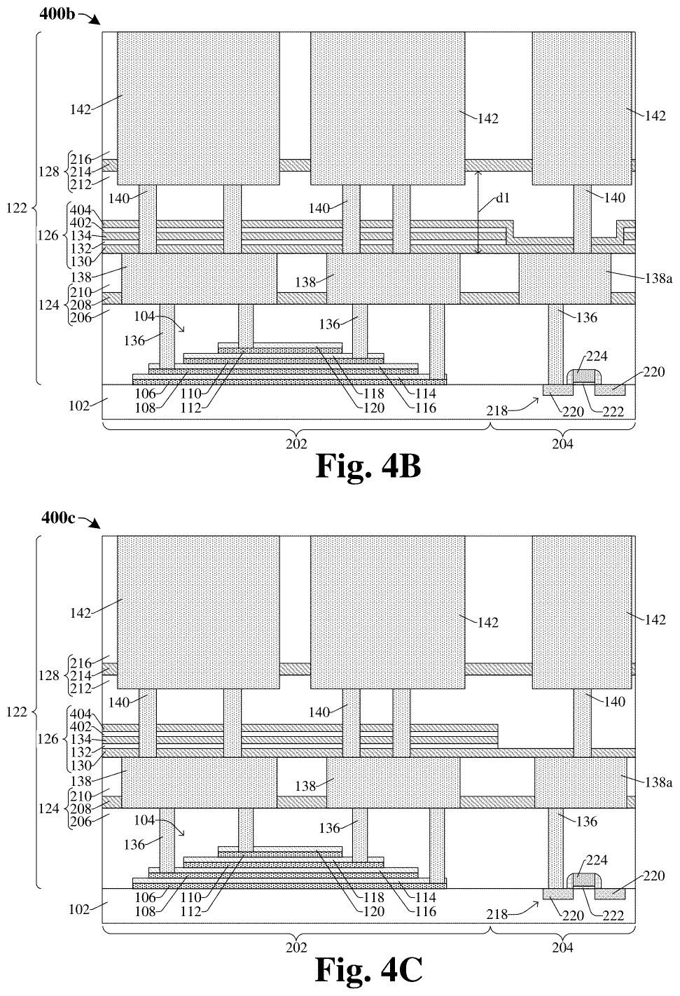

FIG. 4A illustrates a cross-sectional view 400a of some alternative embodiments of an IC including an etch stop structure disposed along first conductive wires, where the etch stop structure comprises a first etch stop layer, a first insulator layer, a second etch stop layer, a second insulator layer, and a third etch stop layer.

In some embodiments, the etch stop structure 126 comprises the first etch stop layer 130, the first insulator layer 132, the second etch stop layer 134, a second insulator layer 402, and a third etch stop layer 404. The first etch stop layer 130 continuously extends along top surfaces of the first conductive wires 138 and a top surface of the first IMD layer 210. The first insulator layer 132 overlies the first etch stop layer 130 and the second etch stop layer 134 overlies the first insulator layer 132. The second insulator layer 402 overlies the second etch stop layer 134 and the third etch stop layer 404 overlies the second insulator layer 402.

The first etch stop layer 130 has a first thickness t1, the first insulator layer 132 has a second thickness t2, the second etch stop layer 134 has a third thickness t3, the second insulator layer 402 has a fourth thickness t4, and the third etch stop layer 404 has a fifth thickness t5. In some embodiments, the first thickness t1 is greater than the third and fifth thicknesses t3, t5, and the third and fifth thicknesses t3, t5 are greater than the second and fourth thicknesses t2, t4. In some embodiments, the first thickness t1 may be within a range of about 50 to 350 angstroms, within a range of about 350 to 750 angstroms, within a range of about 50 to 750 angstroms, or some other suitable value. In various embodiments, the second and fourth thicknesses t2, t4 may be within a range of about 50 to 175 angstroms, within a range of about 175 to 300 angstroms, within a range of about 50 to 300 angstroms, or some other suitable value. In yet further embodiments, the third and fifth thicknesses t3, t5 may be within a range of about 50 to 275 angstroms, within a range of about 275 to 500 angstroms, within a range of about 50 to 500 angstroms, or some other suitable value.

The first, second, and third etch stop layers 130, 134, 404 may, for example, be or comprise silicon nitride, silicon carbide, silicon carbon-nitride, silicon oxycarbide, silicon oxynitride, a high-k dielectric material, some other dielectric material, or any combination of the foregoing. The first and second insulator layers 132, 402 may, for example, be or comprise a low-k dielectric material, PSG, BPSG, an oxide such as silicon dioxide, another suitable dielectric material, or any combination of the foregoing. In various embodiments, the first, second, and third etch stop layers 130, 134, 404 comprise a first dielectric material (e.g., silicon nitride) and the first and second insulator layers 132, 402 comprise a second dielectric material (e.g., silicon dioxide) different from the first dielectric material. In yet further embodiments, the first, second, and third etch stop layers 130, 134, 404 comprise different materials from one another. For example, the first etch stop layer 130 may comprise silicon nitride, the second etch stop layer 134 may comprise silicon carbide, and the third etch stop layer 404 may comprise silicon carbon nitride. In various embodiments, the first and second insulator layers 132, 402 may comprise different materials from one another. For example, the first insulator layer 132 may comprise silicon dioxide and the second insulator layer 402 may comprise PSG.

In some embodiments, by virtue of the etch stop structure 126 further comprising the second insulator layer 402 and the third etch stop layer 404, damage to the first conductive wires 138 during fabrication of the IC of FIG. 4A (e.g., during the etching process utilized to form the conductive vias 140 and/or the second conductive wires 142) may be further reduced. This further mitigates defects in the interconnect structure 122 and reduces damage to the capacitor 104, thereby increasing an overall performance and stability of the IC.

FIG. 4B illustrates a cross-sectional view 400b of some alternative embodiments of the IC of FIG. 4A, in which the third etch stop layer 404 has a U-shape directly above a first conductive wires 138a within the second region 204. In further embodiments, the first insulator layer 132, the second etch stop layer 134, and the second insulator layer 402 are discontinuous within the second region 204 where the third etch stop layer 404 has the U-shape. In such embodiments, the first insulator layer 132, the second etch stop layer 134, and the second insulator layer 402 contact sidewalls of the third etch stop layer 404 that at least partially define the U-shape. In addition, the second IMD layer 212 comprises a protrusion within the second region 204 that extends below a top surface of the etch stop structure 126. In some embodiments, the third etch stop layer 404 directly contacts a top surface of the first etch stop layer 130.

FIG. 4C illustrates a cross-sectional view 400c of some alternative embodiments of the IC of FIG. 4A, in which the first insulator layer 132, the second etch stop layer 134, the second insulator layer 402, and the third etch stop layer 404 are laterally offset from the second region 204. In some embodiments, the second IMD layer 212 continuously extends from a top surface of the third etch stop layer 404, along sidewalls of the third etch stop layer 404, the second insulator layer 402, the second etch stop layer 134, and the first insulator layer 132, to the top surface of the first etch stop layer 130. In various embodiments, the first insulator layer 132, the second etch stop layer 134, the second insulator layer 402, and the third etch stop layer 404 are discontinuous in a region directly above a first conductive wire 138a within the second region 204. In further embodiments, the second IMD layer 212 comprises a protrusion in the second region 204 that extends below the top surface of the etch stop structure 126.

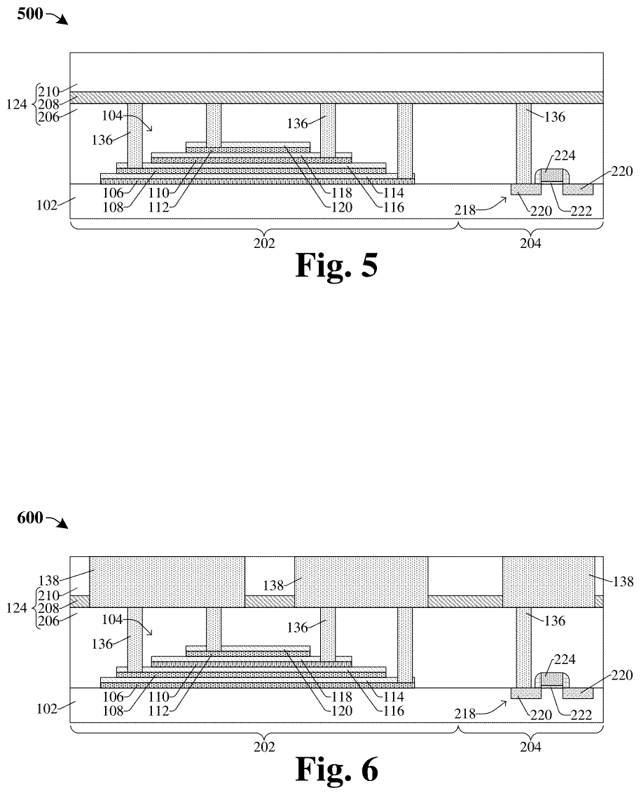

FIGS. 5-14 illustrate cross-sectional views 500-1400 of some embodiments of a method for forming an IC comprising an etch stop structure disposed along first conductive wires, where the etch stop structure comprises a first etch stop layer, a first insulator layer, and a second etch stop layer. Although the cross-sectional views 500-1400 shown in FIGS. 5-14 are described with reference to a method, it will be appreciated that the structures shown in FIGS. 5-14 are not limited to the method but rather may stand alone separate of the method. Furthermore, although FIGS. 5-14 are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part.

As shown in cross-sectional view 500 of FIG. 5, a capacitor 104 is formed within a first region 202 of a semiconductor substrate 102 and a semiconductor device 218 is formed within a second region of the semiconductor substrate 102. The semiconductor substrate 102 may, for example, be or comprise a bulk silicon substrate, a SOI substrate, or some other suitable substrate. The capacitor 104 and the semiconductor device 218 may each be formed by one or more deposition process(es), one or more photolithography process(es), one or more ion implantation process(es), other suitable fabrication processes, or the like.

In addition, as shown in FIG. 5, a plurality of conductive contacts 136 and lower dielectric structure 124 are formed over the semiconductor substrate 102. The lower dielectric structure 124 comprises an ILD layer 206, a first dielectric protection layer 208, and a first IMD layer 210. The lower ILD layer 206, the first dielectric protection layer 208, and the first IMD layer 210 may, for example, be deposited by chemical vapor deposition (CVD), physical vapor deposition (PVD), atomic layer deposition (ALD), or another suitable growth or deposition process. The ILD layer 206 and the first IMD layer 210 may, for example, be or comprise an oxide, such as silicon dioxide, a low-k dielectric material, phosposilicate glass (PSG), borophosphosilicate glass (BPSG), an extreme low-k (ELK) dielectric material, another suitable dielectric material, or any combination of the foregoing. The first dielectric protection layer 208 may, for example, be or comprise silicon nitride, silicon carbide, silicon oxynitride, silicon oxycarbide, or the like. Further, the conductive contacts 136 may be formed within the ILD layer 206. In some embodiments, the conductive contacts 136 may be formed by a single damascene process or some other suitable fabrication process. The conductive contacts 136 may, for example, be or comprise aluminum, copper, tungsten, ruthenium, titanium nitride, tantalum nitride, another suitable conductive material, or any combination of the foregoing.

As shown in cross-sectional view 600 of FIG. 6, a plurality of first conductive wires 138 is formed within the lower dielectric structure 124. In some embodiments, a process for forming the first conductive wires 138 may include: forming a masking layer (not shown) over the first IMD layer 210; performing an etching process on the first IMD layer 210 and the first dielectric protection layer 208 with the masking layer in place to form a plurality of openings; depositing (e.g., by CVD, PVD, sputtering, electroplating, electroless plating, etc.) a conductive material (e.g., aluminum, copper, ruthenium, titanium nitride, tantalum nitride, etc.) in the plurality of openings; and performing a planarization process (e.g., a chemical mechanical planarization (CMP) process) on the conductive material. In some embodiments, the first conductive wires 138 are part of a first layer of conductive wires (e.g., a bottommost layer of conductive wires), where the first conductive wires 138 have a shortest distance to a front-side surface 102f of the semiconductor substrate 102 relative to other conductive wires (e.g., 142 of FIG. 14) formed over the semiconductor substrate 102.

As shown in cross-sectional view 700 of FIG. 7, an etch stop structure 126 is formed on the plurality of first conductive wires 138 and the lower dielectric structure 124. In some embodiments, the etch stop structure 126 comprises a first etch stop layer 130, a first insulator layer 132 disposed on the first etch stop layer 130, and a second etch stop layer 134 disposed on the first insulator layer 132. In various embodiments, a process for forming the etch stop structure 126 includes: performing a first deposition process (e.g., a CVD process, a PVD process, an ALD process, etc.) to deposit the first etch stop layer 130 over the first conductive wires 138; performing a second deposition process (e.g., a CVD process, a PVD process, an ALD process, etc.) to deposit the first insulator layer 132 on the first etch stop layer 130; and performing a third deposition process (e.g., a CVD process, a PVD process, an ALD process, etc.) to deposit the second etch stop layer 134 on the first insulator layer 132.

In some embodiments, the first etch stop layer 130 may, for example, be or comprise silicon nitride, silicon carbide, silicon carbon-nitride, silicon oxycarbide, silicon oxynitride, a high-k dielectric material, or the like and may be formed to a first thickness t1 that is within a range of about 50 to 350 angstroms, within a range of about 350 to 750 angstroms, within a range of about 50 to 750 angstroms, or some other suitable value. The first insulator layer 132 may, for example, be or comprise a low-k dielectric material, PSG, BPSG, an oxide such as silicon dioxide, or the like and may be formed to a second thickness t2 that is within a range of about 50 to 175 angstroms, within a range of about 175 to 300 angstroms, within a range of about 50 to 300 angstroms, or some other suitable value. The second etch stop layer 134 may, for example, be or comprise silicon nitride, silicon carbide, silicon carbon-nitride, silicon oxycarbide, silicon oxynitride, a high-k dielectric material, or the like and may be formed to a third thickness t3 that is within a range of about 50 to 275 angstroms, within a range of about 275 to 500 angstroms, within a range of about 50 to 500 angstroms, or some other suitable value.

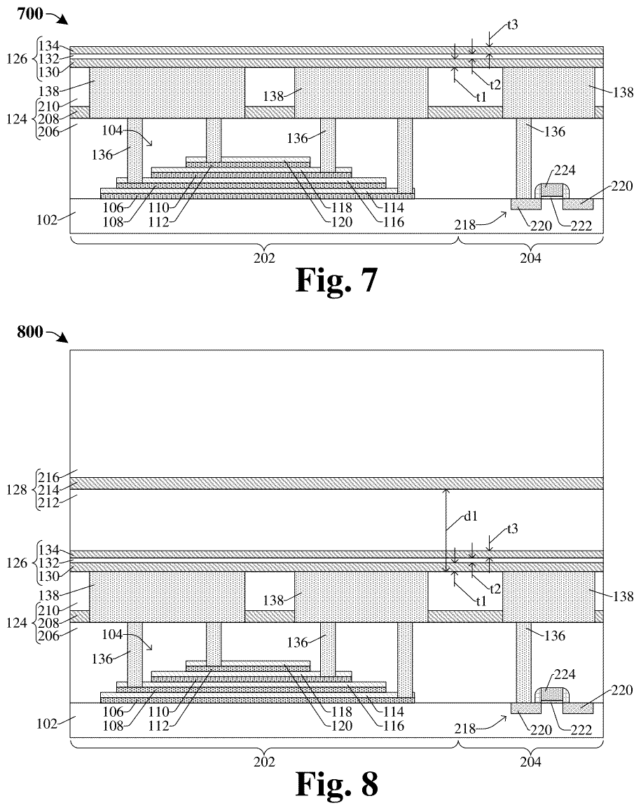

As shown in cross-sectional view 800 of FIG. 8, an upper dielectric structure 128 is formed over the etch stop structure 126. In some embodiments, the upper dielectric structure 128 comprises a second IMD layer 212, a second dielectric protection layer 214, and a third IMD layer 216. In various embodiments, the second IMD layer 212, the second dielectric protection layer 214, and the third IMD layer 216 may, for example, each be deposited by an individual deposition process such as a CVD process, a PVD process, an ALD process, or another suitable growth or deposition process. The second and third IMD layers 212, 216 may, for example, be or comprise an oxide, such as silicon dioxide, a low-k dielectric material, PSG, BPSG, an ELK dielectric material, or the like. The second dielectric protection layer 214 may, for example, be or comprise silicon nitride, silicon carbide, silicon oxynitride, silicon oxycarbide, or the like.

In various embodiments, the upper dielectric structure 128 is formed such that a distance d1 is defined between a top surface of the lower dielectric structure 124 and a bottom surface of the second dielectric protection layer 214. In some embodiments, the top surface of the lower dielectric structure 124 is aligned with or co-planar with the top surfaces of the first conductive wires 138. In some embodiments, the distance d1 may, for example, be within a range of about 4,000 to 6,500 angstroms, within a range of about 6,500 to 9,000 angstroms, within a range of about 4,000 to 9,000 angstroms, or some other suitable value. In various embodiments, a ratio between the third thickness t3 of the second etch stop layer 134 and the distance d1 (e.g., t3:d1) is within a range of about 1:20 to 1:33 or some other suitable value. In further embodiments, a ratio between the second thickness t2 of the first insulator layer 132 and the distance d1 (e.g., t2:d1) is within a range of about 1:25 to 1:35 or some other suitable value. In yet further embodiments, a sum of the second thickness t2 and the third thickness t3 (e.g., t2+t3) is greater than about 300 angstroms.

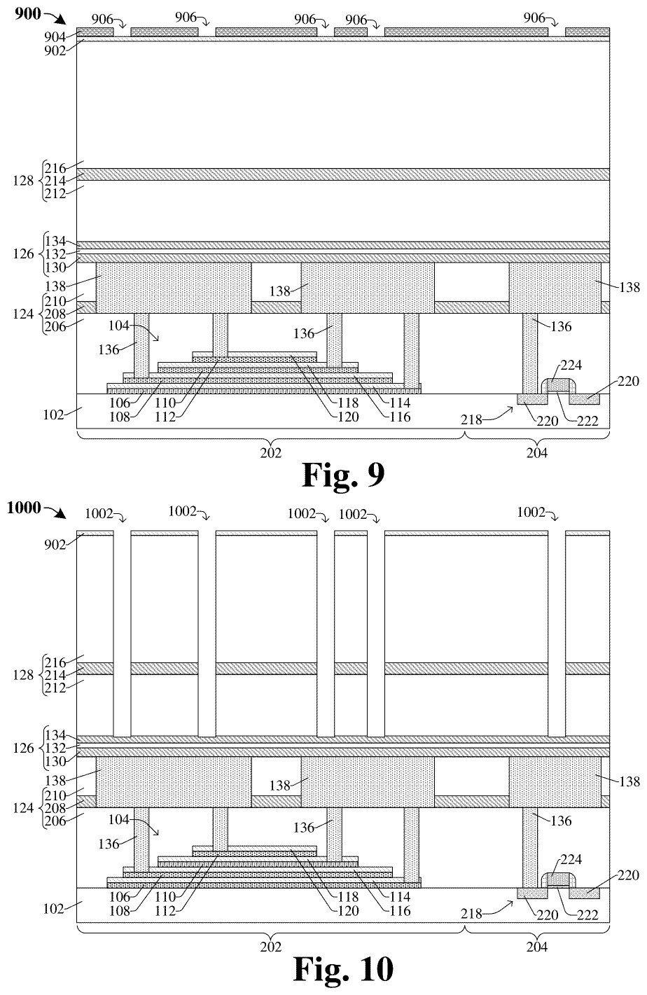

As shown in cross-sectional view 900 of FIG. 9, an upper dielectric layer 902 and a first masking layer 904 are formed over the upper dielectric structure 128. The first masking layer 904 comprises a plurality of sidewalls that define openings 906.

As shown in cross-sectional view 1000 of FIG. 10, a first etch process is performed on the upper dielectric structure 128 to form openings 1002 in the upper dielectric structure 128. In some embodiments, the first etch process may be or comprise an inductively coupled plasma (ICP) process, a capacitively coupled plasma (CCP) process, an ion beam etching (IBE) process, or the like that uses one or more etchant gases formed by a plasma source. The one or more etchant gases may, for example, be or comprise argon, methane (e.g., CH₄), another suitable etchant, or any combination of the foregoing. In various embodiments, the first etch process may be performed in a processing chamber where the one or more etchant gases and oxygen and/or carbon monoxide are flowed in the process chamber comprising the semiconductor substrate 102. The first etch process may include performing an initial etch followed by a final etch. In some embodiments, the initial etch is high powered and comprises forming the one or more etchant gases by the plasma source at a power in a range of about 2,000 to 3,500 watts or another suitable value. In further embodiments, the final etch is low powered and comprises forming the one or more etchant gases by the plasma source at a power of about 500 watts, in a range of about 450 to 550 watts, or another suitable value. The initial etch may etch through the third IMD layer 216, the second dielectric protection layer 214, and at least a portion of the second IMD layer 212. In various embodiments, the final etch may etch through at least a lower portion of the second IMD layer 212 and exposes a top surface of the etch stop structure 126. In further embodiments, after the first etch process a removal process is performed to remove the first masking layer (904 of FIG. 9). Further, a cleaning process (e.g., a wet etch) may be performed on the structure of FIG. 10 after the first etch process.

In various embodiments, due to materials, thicknesses, and a layout of the layers in the etch stop structure 126, damage (e.g., formation of pin holes) to the etch stop structure 126 is reduced and injection of charge carriers (e.g., electrons) in the first conductive wires 138 is mitigated during the first etch process. Since damage to the etch stop structure 126 is mitigated during the first etch process, one or more processing liquids (e.g., etch etchants) utilized during the cleaning process may not reach the first conductive wires 138. As a result, galvanic corrosion and/or diffusion of conductive material (e.g., copper) from the first conductive wires 138 is/are reduced such that defects (e.g., VIMIC) in the conductive contacts 136, the first conductive wires 138, and other metallization layers (e.g., the conductive vias 140, and the second conductive wires 142 of FIG. 14) are mitigated. Accordingly, forming the etch stop structure 126 on the first conductive wires 138 increases the reliability and/or performance of electrical connections between the capacitor 104 and overlying metallization layers (e.g., the conductive contacts 136, the first conductive wires 138, etc.), thereby increasing an overall performance of the IC.

As shown in cross-sectional view 1100 of FIG. 11, a plurality of plugs 1102 is formed within the plurality of openings 1002. A top surface of the plurality of plugs 1102 is disposed below a top surface of the upper dielectric structure 128.

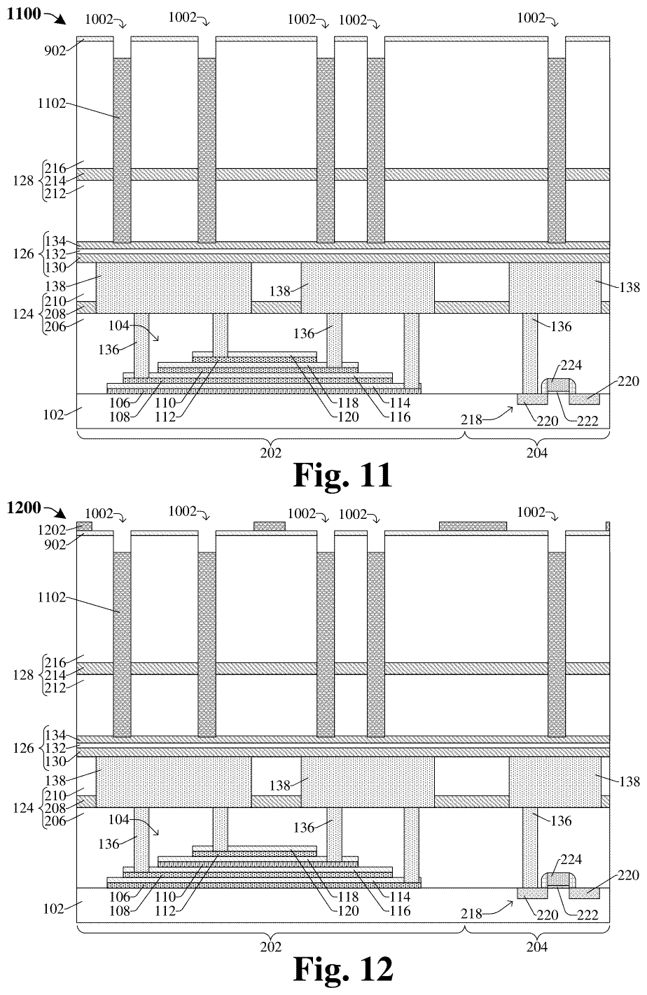

As shown in cross-sectional view 1200 of FIG. 12, a second masking layer 1202 is formed over the upper dielectric layer 902. The second masking layer 1202 comprises sidewalls laterally offset from the plurality of openings 1002.

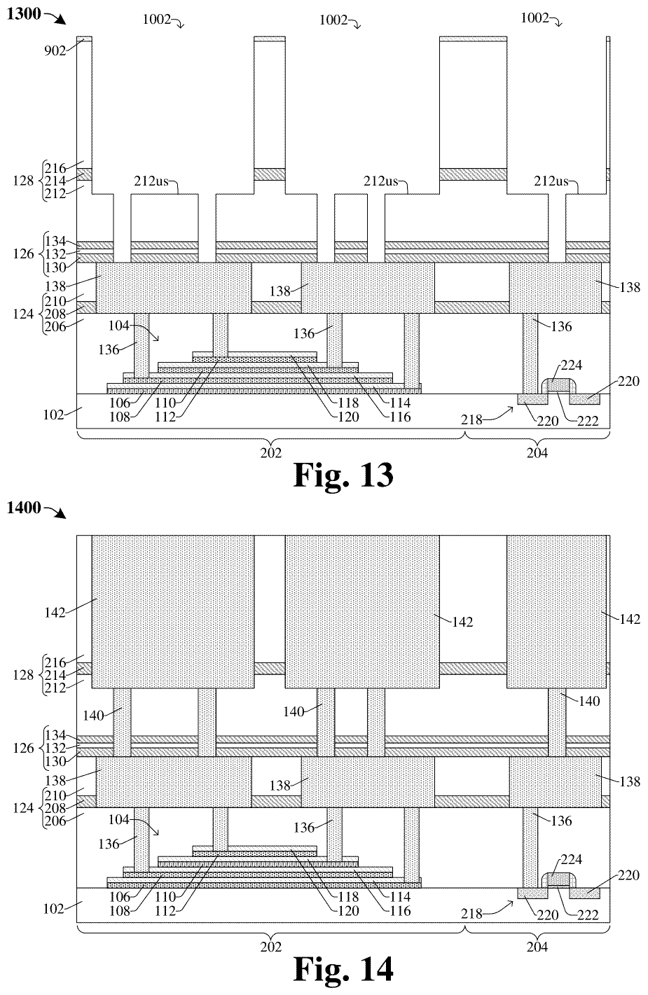

As shown in cross-sectional view 1300 of FIG. 13, a second etch process is performed on the upper dielectric structure 128 and the etch stop structure 126 to expand the openings 1002. In various embodiments, the openings 1002 each comprise a wire opening directly over one or more via opening(s). In some embodiments, the second etch process includes: performing a main etch at a first power level; performing an intermediate etch at a second power level; and performing a low power etch at a third power level. Further, a cleaning process (e.g., a wet etch) may be performed on the structure of FIG. 13 after the second etch process.

In various embodiments, the intermediate etch is performed immediately after the main etch, and the low power etch is performed immediately after the intermediate etch. In further embodiments, the main etch, the intermediate etch, and the low power etch may, for example, be or comprise an ICP etch, a CCP etch, an IBE etch, or the like that uses one or more etchant gases formed by a plasma source. In some embodiments, the main etch comprises forming the one or more etchant gases by the plasma source at the first power level that is in a range of about 2,500 to 3,500 watts or another suitable value. In further embodiments, the intermediate etch comprises forming the one or more etchant gases by the plasma source at the second power level that is in a range of about 1,100 to 1,300 watts or another suitable value. In yet further embodiments, the low power etch comprises forming the one or more etchant gases by the plasma source at the third power level that is in a range of about 300 to 400 watts or another suitable value. Thus, in some embodiments, the first power level is greater than the second power level and the second power level is greater than the third power level. The one or more etchant gases may, for example, be or comprise argon, methane (e.g., CH₄), another suitable etchant, or any combination of the foregoing. In various embodiments, the second etch process may be performed in a processing chamber where the one or more etchant gases and oxygen and/or carbon monoxide are flowed in the process chamber comprising the semiconductor substrate 102.

In some embodiments, the main etch removes material from the plugs (1102 of FIG. 12), the third IMD layer 216, and/or the second dielectric protection layer 214 and stops on the second dielectric protection layer 214. In further embodiments, the intermediate etch removes material from the second dielectric protection layer 214, the second IMD layer 212, and the plugs (1102 of FIG. 12) and stops on the etch stop structure 126. In various embodiments, the intermediate etch defines an upper surface 212us of the second IMD layer 212 and removes the plugs (1102 of FIG. 12) from the openings 1002. In yet further embodiments, the low power etch removes material from the etch stop structure 126 and exposes top surfaces of the first conductive wires 138. By virtue of the second power level being less than the first power level and the third power level being less than the second power level damage to the first conductive wires 138 is reduced.

As shown in cross-sectional view 1400 of FIG. 14, a plurality of conductive vias 140 and a plurality of second conductive wires 142 are formed within the plurality of openings (1002 of FIG. 13). In various embodiments, the plurality of conductive vias 140 and the plurality of second conductive wires 142 are formed concurrently. In some embodiments, a process for forming the plurality of conductive vias 140 and the plurality of second conductive wires 142 includes: depositing (e.g., by CVD, PVD, sputtering, electroplating, electroless plating, etc.) a conductive material within the openings (1002 of FIG. 13) and performing a planarization process (e.g., a CMP process) into the conductive material. In various embodiments, the planarization process may remove the upper dielectric layer (902 of FIG. 13). In further embodiments, a removal process may be performed after forming the plurality of second conductive wires 142 to remove the upper dielectric layer (902 of FIG. 13). The plurality of conductive vias 140 and the plurality of second conductive wires 142 may, for example, be or comprise aluminum, copper, tungsten, ruthenium, titanium nitride, tantalum nitride, another suitable conductive material, or any combination of the foregoing.

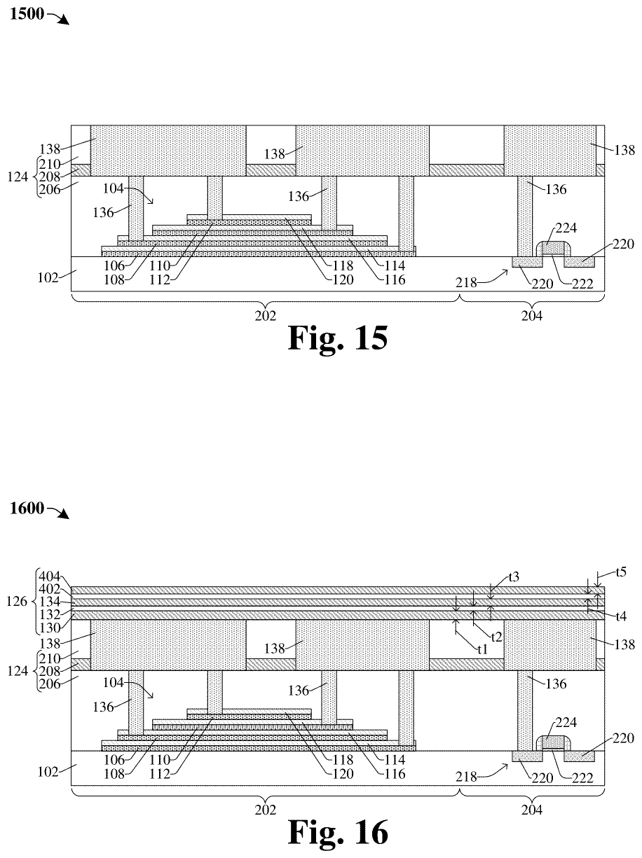

FIGS. 15-21 illustrate cross-sectional views 1500-2100 of some embodiments of a method for forming an IC comprising an etch stop structure disposed along first conductive wires, where the etch stop structure comprises a first etch stop layer, a first insulator layer, a second etch stop layer, a second insulator layer, and a third etch stop layer. Although the cross-sectional views 1500-2100 shown in FIGS. 15-21 are described with reference to a method, it will be appreciated that the structures shown in FIGS. 15-21 are not limited to the method but rather may stand alone separate of the method. Furthermore, although FIGS. 15-21 are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part.

As shown in cross-sectional view 1500 of FIG. 15, a capacitor 104 is formed within a first region 202 of a semiconductor substrate 102 and a semiconductor device 218 is formed within a second region of the semiconductor substrate 102. Further, a lower dielectric structure 124, a plurality of conductive contacts 136, and a plurality of first conductive wires 138 are formed over the semiconductor substrate 102. The structure of FIG. 15 may, for example, be formed as illustrated and/or described in FIGS. 5 and 6.

As shown in cross-sectional view 1600 of FIG. 16, an etch stop structure 126 is formed on the plurality of first conductive wires 138 and the lower dielectric structure 124. In some embodiments, the etch stop structure 126 comprises a first etch stop layer 130, a first insulator layer 132, a second etch stop layer 134, a second insulator layer 402, and a third etch stop layer 404. In various embodiments, a process for forming the etch stop structure 126 includes: performing a first deposition process (e.g., a CVD process, a PVD process, an ALD process, etc.) to deposit the first etch stop layer 130 over the first conductive wires 138; performing a second deposition process (e.g., a CVD process, a PVD process, an ALD process, etc.) to deposit the first insulator layer 132 on the first etch stop layer 130; performing a third deposition process (e.g., a CVD process, a PVD process, an ALD process, etc.) to deposit the second etch stop layer 134 on the first insulator layer 132; performing a fourth deposition process (e.g., a CVD process, a PVD process, an ALD process, etc.) to deposit the second insulator layer 402 on the second etch stop layer 134; and performing a fifth deposition process (e.g., a CVD process, a PVD process, an ALD process, etc.) to deposit the third etch stop layer 404 on the second insulator layer 402.

The first, second, and third etch stop layers 130, 134, 404 may, for example, be or comprise silicon nitride, silicon carbide, silicon carbon-nitride, silicon oxycarbide, silicon oxynitride, a high-k dielectric material, some other dielectric material, or any combination of the foregoing. The first and second insulator layers 132, 402 may, for example, be or comprise a low-k dielectric material, PSG, BPSG, an oxide such as silicon dioxide, another suitable dielectric material, or any combination of the foregoing. The first etch stop layer 130 is formed to a first thickness t1, the first insulator layer 132 is formed to a second thickness t2, the second etch stop layer 134 is formed to a third thickness t3, the second insulator layer 402 is formed to a fourth thickness t4, and the third etch stop layer 404 is formed to a fifth thickness t5. In some embodiments, the first thickness t1 may be within a range of about 50 to 350 angstroms, within a range of about 350 to 750 angstroms, within a range of about 50 to 750 angstroms, or some other suitable value. In various embodiments, the second and fourth thicknesses t2, t4 may be within a range of about 50 to 175 angstroms, within a range of about 175 to 300 angstroms, within a range of about 50 to 300 angstroms, or some other suitable value. In yet further embodiments, the third and fifth thicknesses t3, t5 may be within a range of about 50 to 275 angstroms, within a range of about 275 to 500 angstroms, within a range of about 50 to 500 angstroms, or some other suitable value.

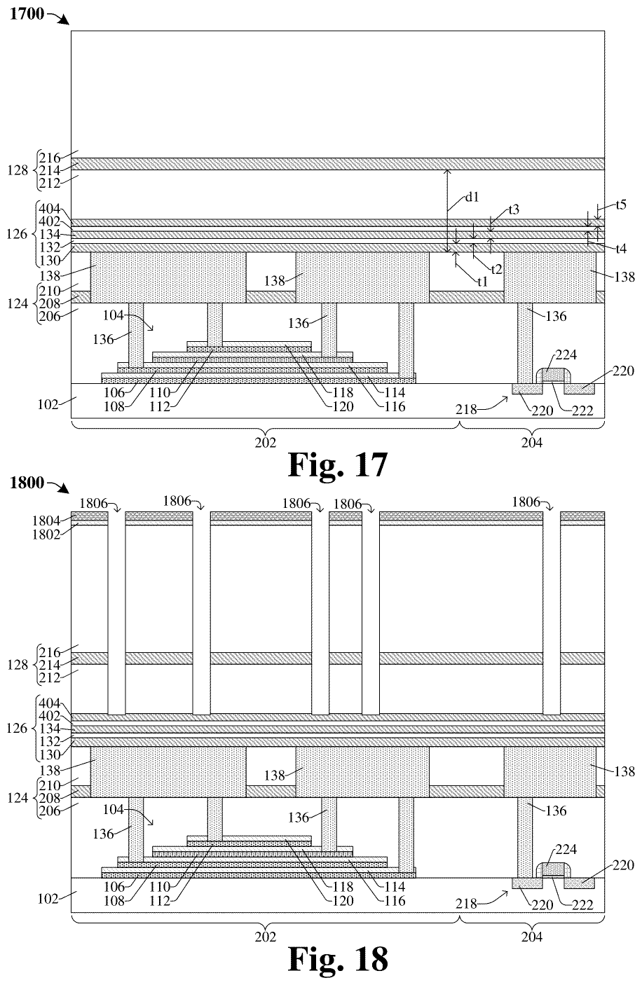

As shown in cross-sectional view 1700 of FIG. 17, an upper dielectric structure 128 is formed over the etch stop structure 126. In some embodiments, the upper dielectric structure 128 comprises a second IMD layer 212, a second dielectric protection layer 214, and a third IMD layer 216. In various embodiments, the second IMD layer 212, the second dielectric protection layer 214, and the third IMD layer 216 may, for example, each be deposited by an individual deposition process such as a CVD process, a PVD process, an ALD process, or another suitable growth or deposition process.

As shown in cross-sectional view 1800 of FIG. 18, an upper dielectric layer 1802 and a first masking layer 1804 are formed over the upper dielectric structure 128. Further, a first etch process is performed on the upper dielectric structure to form openings 1806 in the upper dielectric structure 128. In some embodiments, the first etch process of FIG. 18 may, for example, be performed as illustrated and/or described as the first etch process of FIG. 10. In such embodiments, the first etch process comprises performing an initial etch (e.g., a high powered etched where one or more etchant gases are formed by a plasma source at a power in a range of about 2,000 to 3,500 watts) followed by a final etch (e.g., a low powered etch where one or more etchants gases are formed by a plasma source at a power of about 500 watts or in a range of about 450 to 550 watts). Further, a cleaning process (e.g., a wet etch) may be performed on the structure of FIG. 18 after the first etch process.

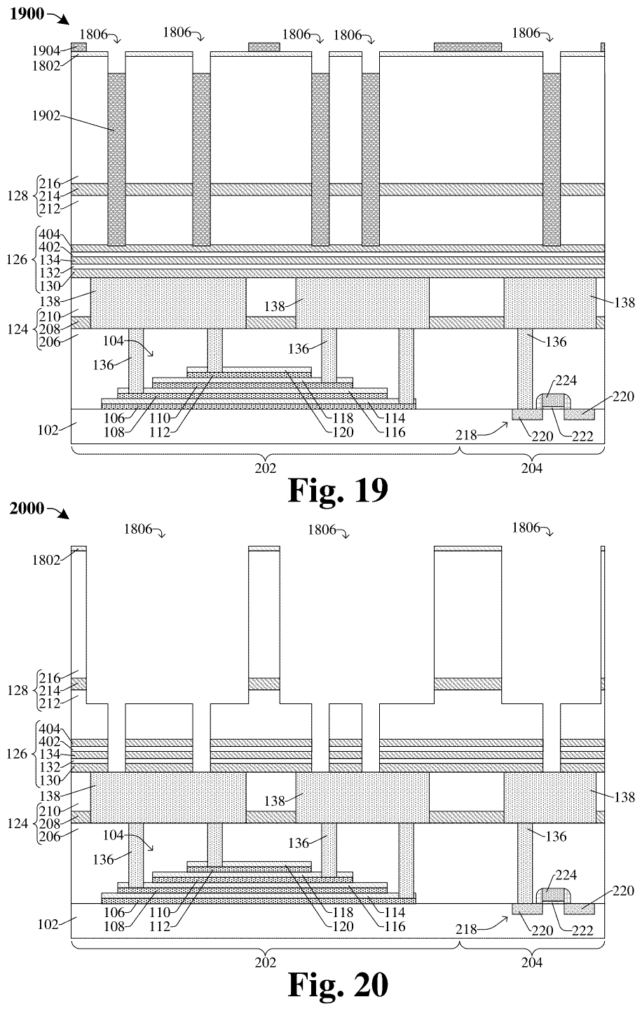

As shown in cross-sectional view 1900 of FIG. 19, a plurality of plugs 1902 is formed within the plurality of openings 1806 and a second masking layer 1904 is formed over the upper dielectric layer 1802.

As shown in cross-sectional view 2000 of FIG. 20, a second etch process is performed on the upper dielectric structure 128 and the etch stop structure 126 to expand the openings 1806. In various embodiments, the openings 1806 each comprise a wire opening directly over one or more via opening(s). In some embodiments, the second etch process of FIG. 20 may, for example, be performed as illustrated and/or described as the second etch process of FIG. 13. In such embodiments, the second etch process comprises: performing a main etch, where one or more etchant gases are formed by a plasma source at a first power level that is within a range of about 2,500 to 3,500 watts; performing an intermediate etch, where the one or more etchant gases are formed by the plasma source at a second power level that is within a range of about 1,100 to 1,300 watts; and performing a low power etch, where the one or more etchant gases are formed by the plasma source at a third power level that is within a range of about 300 to 400 watts. Further, a cleaning process (e.g., a wet etch) may be performed on the structure of FIG. 20 after the second etch process.

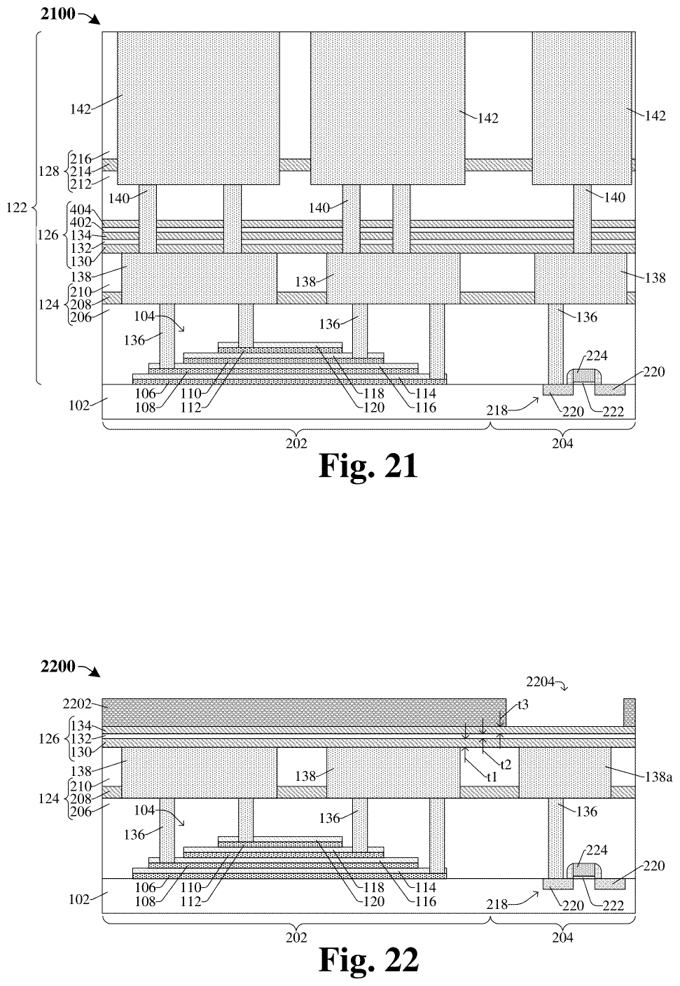

As shown in cross-sectional view 2100 of FIG. 21, a plurality of conductive vias 140 and a plurality of second conductive wires 142 are formed within the plurality of openings (1806 of FIG. 20). In various embodiments, the plurality of conductive vias 140 and the plurality of second conductive wires 142 are formed concurrently. In some embodiments, a process for forming the plurality of conductive vias 140 and the plurality of second conductive wires 142 includes: depositing (e.g., by CVD, PVD, sputtering, electroplating, electroless plating, etc.) a conductive material within the openings (1806 of FIG. 20) and performing a planarization process (e.g., a CMP process) into the conductive material. In various embodiments, the planarization process may remove the upper dielectric layer (1802 of FIG. 20). In further embodiments, a removal process may be performed after forming the plurality of second conductive wires 142 to remove the upper dielectric layer (1802 of FIG. 20).

FIGS. 22-24 illustrate cross-sectional views 2200-2400 of some embodiments of acts that may be performed in place of the act(s) at FIG. 8, such that the method of FIGS. 5-14 may alternatively proceed from FIGS. 5-7 to FIGS. 22-24 and then from FIG. 24 to FIGS. 9-14 (i.e., skipping FIG. 8). Although the cross-sectional views 2200-2400 shown in FIGS. 22-24 are described with reference to a method, it will be appreciated that the structures shown in FIGS. 22-24 are not limited to the method but rather may stand alone separate of the method. Further, although FIGS. 22-24 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in cross-sectional view 2200 of FIG. 22, a masking layer 2202 is formed over the etch stop structure 126. The masking layer 2202 comprises sidewalls defining an opening 2204 over a first conductive wire 138a within the second region 204. The opening 2204 exposes a top surface of the etch stop structure 126 in the second region 204.

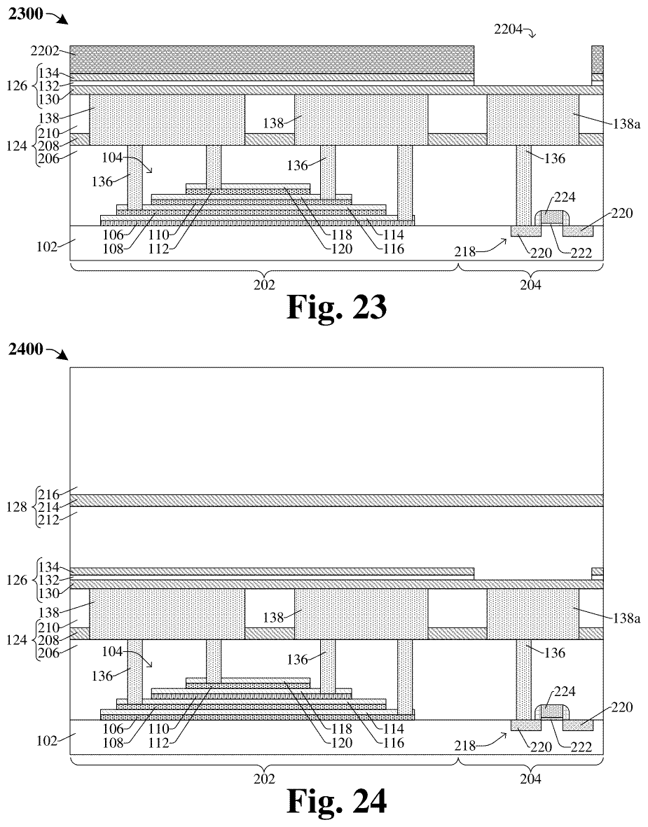

As shown in cross-sectional view 2300 of FIG. 23, an etch process is performed on the etch stop structure 126 to remove at least a portion of the first insulator layer 132 and the second etch stop layer 134 from above the first conductive wire 138a disposed within the second region 204. In various embodiments, the etch process includes performing a plasma etching process, a dry etch process followed by a wet etch process, or some other suitable etching process. After the etch process a top surface of the first etch stop layer 130 is exposed within the second region 204. In some embodiments, after the etch process the first insulator layer 132 and the second etch stop layer 134 are discontinuous within the second region 204.

As shown in cross-sectional view 2400 of FIG. 24, an upper dielectric structure 128 is formed over the etch stop structure 126. In some embodiments, the upper dielectric structure 128 comprises a second IMD layer 212, a second dielectric protection layer 214, and third IMD layer 216. In various embodiments, the second IMD layer 212, the second dielectric protection layer 214, and the third IMD layer 216 may, for example, each be deposited by an individual deposition process such as a CVD process, a PVD process, an ALD process, or another suitable growth or deposition process. In various embodiments, the second IMD layer 212 is formed such that the second IMD layer 212 comprises a protrusion within the second region 204 that extends below a top surface of the etch stop structure 126 and contacts sidewalls of the first insulator layer 132 and sidewalls of the second etch stop layer 134.

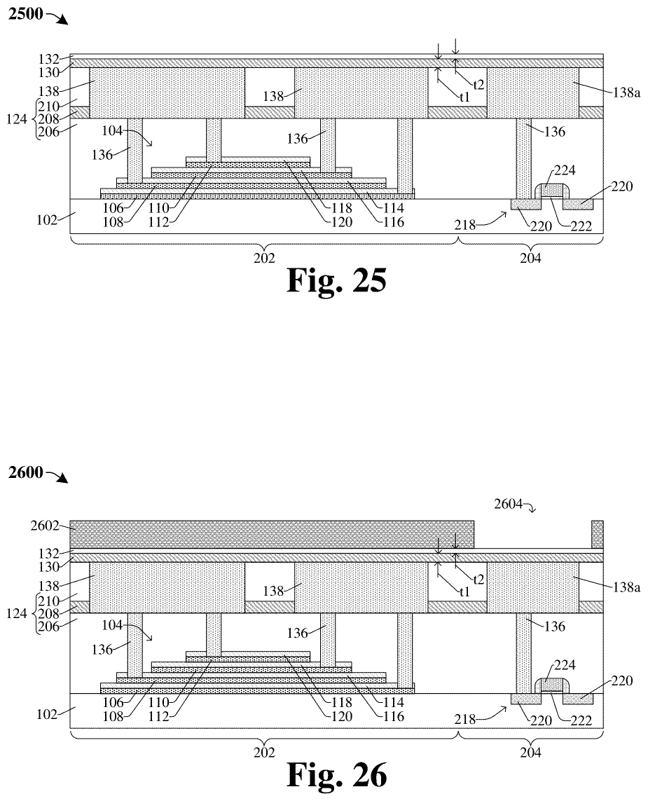

FIGS. 25-29 illustrate cross-sectional views 2500-2900 of some embodiments of acts that may be performed in place of the acts at FIGS. 7 and 8, such that the method of FIGS. 5-14 may alternatively proceed from FIGS. 5 and 6 to FIGS. 25-29 and then from FIG. 29 to FIGS. 9-14 (i.e., skipping FIGS. 7 and 8). Although the cross-sectional views 2500-2900 shown in FIGS. 25-29 are described with reference to a method, it will be appreciated that the structures shown in FIGS. 25-29 are not limited to the method but rather may stand alone separate of the method. Further, although FIGS. 25-29 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in cross-sectional view 2500 of FIG. 25, a first etch stop layer 130 is formed over the first conductive wires 138 and a first insulator layer 132 is formed on the first etch stop layer 130. In some embodiments, the first etch stop layer 130 and the first insulator layer 132 may, for example, each be deposited by an individual deposition process such as a CVD process, a PVD process, an ALD process, or another suitable growth or deposition process. In various embodiments, the first etch stop layer 130 is formed to a first thickness t1 and the first insulator layer 132 is formed to a second thickness t2 that is less than the first thickness t1.

As shown in cross-sectional view 2600 of FIG. 26, a masking layer 2602 is formed over the first insulator layer 132. The masking layer 2602 comprises sidewalls defining an opening 2604 over a first conductive wire 138a within the second region 204. The opening 2604 exposes a top surface of the first insulator layer 132 in the second region 204.

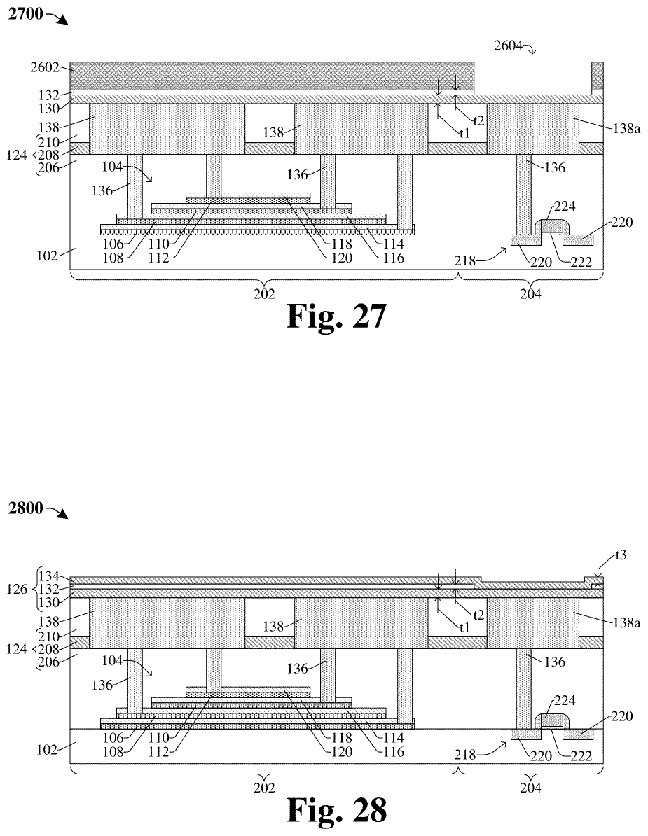

As shown in cross-sectional view 2700 of FIG. 27, an etch process is performed on the first insulator layer 132 to remove at least a portion of the first insulator layer 132 from above the first conductive wire 138a disposed within the second region 204. In some embodiments, the etch process includes performing a dry etch process, a wet etch process, or a combination of the foregoing. After the etch process a top surface of the first etch stop layer 130 is exposed within the second region 204. In various embodiments, after the etch process the first insulator layer 132 is discontinuous within the second region 204.

As shown in cross-sectional view 2800 of FIG. 28, a second etch stop layer 134 is formed over the first insulator layer 132, thereby defining an etch stop structure 126. In some embodiments, the etch stop structure 126 comprises the first etch stop layer 130, the first insulator layer 132, and the second etch stop layer 134. In various embodiments, the second etch stop layer 134 may be formed by a deposition process such as, for example, a CVD process, a PVD process, an ALD process, or another suitable growth or deposition process. In further embodiments, the second etch stop layer 134 comprises a U-shape within the second region 204 directly above the first conductive wire 138a. In some embodiments, the second etch stop layer 134 directly contacts the top surface of the first etch stop layer 130 and is formed to a third thickness t3 that is greater than the second thickness t2.

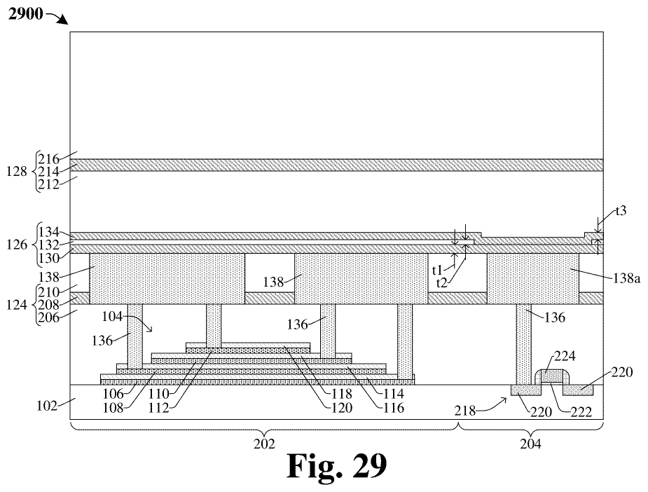

As shown in cross-sectional view 2900 of FIG. 29, an upper dielectric structure 128 is formed over the etch stop structure 126. In some embodiments, the upper dielectric structure 128 comprises a second IMD layer 212, a second dielectric protection layer 214, and third IMD layer 216. In various embodiments, the second IMD layer 212, the second dielectric protection layer 214, and the third IMD layer 216 may, for example, each be deposited by an individual deposition process such as a CVD process, a PVD process, an ALD process, or another suitable growth or deposition process. In various embodiments, the second IMD layer 212 is formed such that the second IMD layer 212 comprises a protrusion within the second region 204 that extends below a top surface of the etch stop structure 126 and contacts inner sidewalls of the second etch stop layer 134.

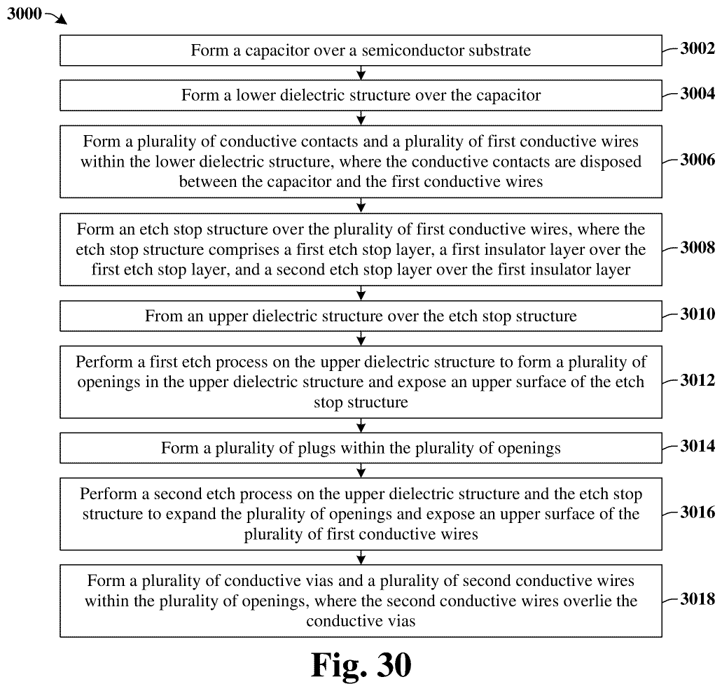

FIG. 30 illustrates a method 3000 of forming an integrated circuit (IC) comprising an etch stop structure disposed along first conductive wires, where the etch stop structure comprises a first etch stop layer, a first insulator layer, and a second etch stop layer. Although the method 3000 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 3002, a capacitor is formed over a semiconductor substrate. FIG. 5 illustrates cross-sectional view 500 corresponding to various embodiments of act 3002.

At act 3004, a lower dielectric structure is formed over the capacitor. FIG. 5 illustrates cross-sectional view 500 corresponding to various embodiments of act 3004.

At act 3006, a plurality of conductive contacts and a plurality of first conductive wires are formed within the lower dielectric structure. The conductive contacts are disposed between the capacitor and the first conductive wires. FIGS. 5 and 6 illustrate cross-sectional views 500 and 600 corresponding to various embodiments of act 3006.

At act 3008, an etch stop structure is formed over the plurality of first conductive wires. The etch stop structure comprises a first etch stop layer, a first insulator layer over the first etch stop layer, and a second etch stop layer over the first insulator layer. FIG. 7 illustrates cross-sectional view 700 corresponding to various embodiments of act 3008. FIG. 16 illustrates cross-sectional view 1600 corresponding to some embodiments of act 3008. FIGS. 22 and 23 illustrate cross-sectional views 2200 and 2300 corresponding to some other embodiments of act 3008. FIGS. 25-28 illustrate cross-sectional views 2500-2800 corresponding to further embodiments of act 3008.

At act 3010, an upper dielectric structure is formed over the etch stop structure. FIG. 8 illustrates cross-sectional view 800 corresponding to various embodiments of act 3010. FIG. 17 illustrates cross-sectional view 1700 corresponding to some embodiments of act 3010. FIG. 24 illustrates cross-sectional view 2400 corresponding to some other embodiments of act 3010. FIG. 29 illustrates cross-sectional view 2900 corresponding to further embodiments of act 3010.

At act 3012, a first etch process is performed on the upper dielectric structure to form a plurality of openings in the upper dielectric structure and expose an upper surface of the etch stop structure. FIGS. 9 and 10 illustrate cross-sectional views 900 and 1000 corresponding to some embodiments of act 3012. FIG. 18 illustrates cross-sectional view 1800 corresponding to some other embodiments of act 3012.

At act 3014, a plurality of plugs is formed within the plurality of openings. FIG. 11 illustrates cross-sectional view 1100 corresponding to some embodiments of act 3014. FIG. 19 illustrates cross-sectional view 1900 corresponding to some other embodiments of act 3014.

At act 3016, a second etch process is performed on the upper dielectric structure and the etch stop structure to expand the plurality of openings and expose an upper surface of the plurality of first conductive wires. FIGS. 12 and 13 illustrate cross-sectional views 1200 and 1300 corresponding to some embodiments of act 3016. FIG. 20 illustrates cross-sectional view 2000 corresponding to some other embodiments of act 3016.

At act 3018, a plurality of conductive vias and a plurality of second conductive wires are formed within the plurality of openings. The second conductive wires overlie the conductive vias. FIG. 14 illustrates cross-sectional view 1400 corresponding to some embodiments of act 3018. FIG. 21 illustrates cross-sectional view 2100 corresponding to some other embodiments of act 3018.

Accordingly, in some embodiments, the present disclosure relates to an IC comprising a plurality of first conductive wires coupled to an underlying capacitor and an etch stop structure disposed on a top surface of the plurality of first conductive wires. The etch stop structure comprises a first etch stop layer over the first conductive wires, a first insulator layer over the first etch stop layer, and a second etch stop layer over the first insulator layer.

In some embodiments, the present application provides an integrated circuit (IC) including: a plurality of conductive contacts overlying a semiconductor substrate; a plurality of first conductive wires disposed on the plurality of conductive contacts; a plurality of conductive vias overlying the first conductive wires; and an etch stop structure disposed on the first conductive wires, where the plurality of conductive vias extend through the etch stop structure, and where the etch stop structure includes a first etch stop layer, a first insulator layer, and a second etch stop layer, where the first insulator layer is disposed between the first etch stop layer and the second etch stop layer. In an embodiment the first etch stop layer has a first thickness and the first insulator layer has a second thickness less than the first thickness. In an embodiment the second etch stop layer has a third thickness that is greater than the second thickness and less than the first thickness. In an embodiment the first thickness is within a range of about 50 to 750 angstroms, the second thickness is within a range of about 50 to 300 angstroms, and the third thickness is within a range of about 50 to 500 angstroms. In an embodiment the plurality of first conductive wires is part a bottommost layer of conductive wires overlying the semiconductor substrate, where the first etch stop layer directly contacts top surfaces of the first conductive wires. In an embodiment, the IC further includes a first inter-metal dielectric (IMD) layer overlying the plurality of conductive contacts and disposed around sidewalls of the first conductive wires, where the first etch stop layer continuously extends from a top surface of the first IMD layer to top surfaces of the first conductive wires. In an embodiment the IC further includes a second IMD layer overlying the etch stop structure and disposed around sidewalls of the conductive vias, where the etch stop structure is sandwiched between the first IMD layer and the second IMD layer, and where a thickness of the second IMD layer is greater than a thickness of the etch stop structure. In an embodiment, the IC further includes a plurality of second conductive wires disposed on the plurality of conductive vias, where the second conductive wires contact an upper surface of the second IMD layer. In an embodiment the IC further includes a capacitor disposed between the semiconductor substrate and the plurality of conductive contacts, where the capacitor comprises a plurality of conductive layers, where the conductive vias are electrically coupled to the plurality of conductive layers by way of the conductive contacts and the first conductive wires.

In some embodiments, the present application provides an integrated chip including a capacitor disposed over a semiconductor substrate; a lower dielectric structure overlying the semiconductor substrate; a plurality of first conductive wires disposed within the lower dielectric structure, where the first conductive wires are electrically coupled to the capacitor; and an etch stop structure directly contacting the first conductive wires, where the etch stop structure continuously extends from top surfaces of the first conductive wires to a top surface of the lower dielectric structure, where the etch stop structure includes a first etch stop layer, a first insulator layer over the first etch stop layer, and a second etch stop layer over the first insulator layer, where the first insulator layer directly contacts the first etch stop layer and the second etch stop layer. In an embodiment the lower dielectric structure includes an inter-level dielectric (ILD) layer underlying the first conductive wires, a first dielectric protection layer over the ILD layer, and a first inter-metal dielectric (IMD) layer over the first dielectric protection layer, where the first dielectric protection layer contacts sidewalls of the first conductive wires, and where a thickness of the etch stop structure is greater than a thickness of the first dielectric protection layer. In an embodiment the first dielectric protection layer, the first etch stop layer, and the second etch stop layer respectively comprise a first dielectric material, where the first insulator layer comprises a second dielectric material different from the first dielectric material. In an embodiment the first IMD layer comprises the second dielectric material. In an embodiment the etch stop structure further includes a second insulator layer over the second etch stop layer and a third etch stop layer over the second insulator layer. In an embodiment the first etch stop layer has a thickness greater than a thickness of the second etch stop layer and a thickness of the third etch stop layer, and where the thickness of the first etch stop layer is greater than a thickness of the first insulator layer and a thickness of the second insulator layer.

In some embodiments, the present application provides a method for forming a semiconductor device, the method includes: forming a lower dielectric structure over a semiconductor substrate; forming a plurality of first conductive wires within the lower dielectric structure; forming an etch stop structure over the plurality of first conductive wires, where the etch stop structure includes a first etch stop layer, a first insulator layer, and a second etch stop layer; forming an upper dielectric structure over the etch stop structure; performing a first etch process on the upper dielectric structure to form a plurality of openings in the upper dielectric structure, where the first etch stop process exposes an upper surface of the etch stop structure; and performing a second etch process on the upper dielectric structure and the etch stop structure to expand the plurality of openings, where the second etch process etches through the etch stop structure and exposes upper surfaces of the first conductive wires, where the second etch process includes performing two or more etch processes having different power levels from one another. In an embodiment the first etch process includes performing an initial high powered etch followed by a final low powered etch, where the initial high powered etch comprises forming one or more etchant gases at a first power and the final low powered etch comprises forming the one or more etchant gases at a second power less than the first power. In an embodiment the two or more etch processes include performing a first plasma etch at a first power level, performing a second plasma etch at a second power level, and performing a third plasma etch at a third power level, where the first power level is greater than the second power level and the second power level is greater than the third power level. In an embodiment the second plasma etch is performed immediately after the first plasma etch and the third plasma etch is performed immediately after the second plasma etch. In an embodiment the method further includes forming a capacitor on the semiconductor substrate, where the plurality of first conductive wires is directly electrically coupled to the capacitor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) comprising:
a plurality of conductive contacts overlying a semiconductor substrate;
a plurality of first conductive wires disposed on the plurality of conductive contacts;
a plurality of conductive vias overlying the first conductive wires; and
an etch stop structure disposed on the first conductive wires, wherein the plurality of conductive vias extend through the etch stop structure, and wherein the etch stop structure comprises a first etch stop layer, a first insulator layer, and a second etch stop layer, wherein the first insulator layer is disposed between the first etch stop layer and the second etch stop layer.

2. The IC of claim 1, wherein the first etch stop layer has a first thickness and the first insulator layer has a second thickness less than the first thickness.

3. The IC of claim 2, wherein the second etch stop layer has a third thickness that is greater than the second thickness and less than the first thickness.

4. The IC of claim 3, wherein the first thickness is within a range of about 50 to 750 angstroms, the second thickness is within a range of about 50 to 300 angstroms, and the third thickness is within a range of about 50 to 500 angstroms.

5. The IC of claim 1, wherein the plurality of first conductive wires is part a bottommost layer of conductive wires overlying the semiconductor substrate, wherein the first etch stop layer directly contacts top surfaces of the first conductive wires.

6. The IC of claim 1, further comprising:
a first inter-metal dielectric (IMD) layer overlying the plurality of conductive contacts and disposed around sidewalls of the first conductive wires, wherein the first etch stop layer continuously extends from a top surface of the first IMD layer to top surfaces of the first conductive wires.

7. The IC of claim 6, further comprising:
a second IMD layer overlying the etch stop structure and disposed around sidewalls of the conductive vias, wherein the etch stop structure is sandwiched between the first IMD layer and the second IMD layer, and wherein a thickness of the second IMD layer is greater than a thickness of the etch stop structure.

8. The IC of claim 7, further comprising:
a plurality of second conductive wires disposed on the plurality of conductive vias, wherein the second conductive wires contact an upper surface of the second IMD layer.

9. The IC of claim 1, further comprising:
a capacitor disposed between the semiconductor substrate and the plurality of conductive contacts, wherein the capacitor comprises a plurality of conductive layers, wherein the conductive vias are electrically coupled to the plurality of conductive layers by way of the conductive contacts and the first conductive wires.

10. An integrated chip comprising:
a capacitor disposed over a semiconductor substrate;
a lower dielectric structure overlying the semiconductor substrate;
a plurality of first conductive wires disposed within the lower dielectric structure, wherein the first conductive wires are electrically coupled to the capacitor; and
an etch stop structure directly contacting the first conductive wires, wherein the etch stop structure continuously extends from top surfaces of the first conductive wires to a top surface of the lower dielectric structure, wherein the etch stop structure comprises a first etch stop layer, a first insulator layer over the first etch stop layer, and a second etch stop layer over the first insulator layer, wherein the first insulator layer directly contacts the first etch stop layer and the second etch stop layer.

11. The integrated chip of claim 10, wherein the lower dielectric structure comprises an inter-level dielectric (ILD) layer underlying the first conductive wires, a first dielectric protection layer over the ILD layer, and a first inter-metal dielectric (IMD) layer over the first dielectric protection layer, wherein the first dielectric protection layer contacts sidewalls of the first conductive wires, and wherein a thickness of the etch stop structure is greater than a thickness of the first dielectric protection layer.

12. The integrated chip of claim 11, wherein the first dielectric protection layer, the first etch stop layer, and the second etch stop layer respectively comprise a first dielectric material, wherein the first insulator layer comprises a second dielectric material different from the first dielectric material.

13. The integrated chip of claim 12, wherein the first IMD layer comprises the second dielectric material.

14. The integrated chip of claim 10, wherein the etch stop structure further comprises a second insulator layer over the second etch stop layer and a third etch stop layer over the second insulator layer.

15. The integrated chip of claim 14, wherein the first etch stop layer has a thickness greater than a thickness of the second etch stop layer and a thickness of the third etch stop layer, and wherein the thickness of the first etch stop layer is greater than a thickness of the first insulator layer and a thickness of the second insulator layer.

16. A method for forming a semiconductor device, comprising:
forming a lower dielectric structure over a semiconductor substrate;
forming a plurality of first conductive wires within the lower dielectric structure;
forming an etch stop structure over the plurality of first conductive wires, wherein the etch stop structure comprises a first etch stop layer, a first insulator layer, and a second etch stop layer;
forming an upper dielectric structure over the etch stop structure;
performing a first etch process on the upper dielectric structure to form a plurality of openings in the upper dielectric structure, wherein the first etch stop process exposes an upper surface of the etch stop structure; and
performing a second etch process on the upper dielectric structure and the etch stop structure to expand the plurality of openings, wherein the second etch process etches through the etch stop structure and exposes upper surfaces of the first conductive wires, wherein the second etch process comprises performing two or more etch processes having different power levels from one another.

17. The method of claim 16, wherein the first etch process comprises performing an initial high powered etch followed by a final low powered etch, wherein the initial high powered etch comprises forming one or more etchant gases at a first power and the final low powered etch comprises forming the one or more etchant gases at a second power less than the first power.

18. The method of claim 16, wherein the two or more etch processes comprise performing a first plasma etch at a first power level, performing a second plasma etch at a second power level, and performing a third plasma etch at a third power level, wherein the first power level is greater than the second power level and the second power level is greater than the third power level.

19. The method of claim 18, wherein the second plasma etch is performed immediately after the first plasma etch and the third plasma etch is performed immediately after the second plasma etch.

20. The method of claim 16, further comprising:
forming a capacitor on the semiconductor substrate, wherein the plurality of first conductive wires is directly electrically coupled to the capacitor.
